(19) United States
(12) Patent Application Publication
(10) Pub. No.: US 2026/0344368 A1
(43) Pub. Date: Oct. 29, 2026

(54) PLASMA PROCESSING APPARATUS AND PLASMA PROCESSING METHOD

(71) Applicant: HITACHI HIGH-TECH CORPORATION, Minato-ku, Tokyo (JP)

(72) Inventors: Soichiro ETO, Tokyo (JP); Shigeru Nakamoto, Tokyo (JP); Kosuke Fukuchi, Tokyo (JP)

(21) Appl. No.: 19/107,215

(22) PCT Filed: Sep. 14, 2023
(86) PCT No.: PCT/JP2023/033586

§ 371 Date: Feb. 27, 2025

(51) Int. Cl. H10P 74/00; H01J 37/32

(52) U.S. Cl. CPC H10P 74/238; H01J 37/32935; H01J 2237/334

(57) ABSTRACT

A plasma processing apparatus and method for measuring reflected light reflected at a processing target region regardless of a pattern layout of a device. The plasma processing apparatus includes: a light irradiation unit having a plurality of irradiators configured to emit light to different positions toward a wafer; a light receiving unit configured to receive reflected light emitted from the plurality of irradiators by the wafer; and a processing amount detection unit configured to detect a processing amount of the wafer based on information obtained from the reflected light received by the light receiving unit. The processing amount detection unit determines an irradiator that is to perform light irradiation from among the plurality of irradiators based on a difference between information on reflection positions on the wafer information on processing position of the wafer, and detects the processing amount of the wafer using the determined irradiator.

### TECHNICAL FIELD

The techniques of the present disclosure relate to a plasma processing apparatus and a plasma processing method using the same.

### BACKGROUND ART

A semiconductor device includes, for example, various components and wirings for connecting the components on a surface of a wafer. Such a semiconductor device is formed by repeating film formation of various materials such as a conductor, a semiconductor, and an insulator and removal processing of an unnecessary portion.

Dry etching using plasma is widely used as a process of removing unnecessary portions. In plasma etching, a gas introduced into a processing chamber of an etching apparatus is converted into plasma by a radio frequency power supply or the like, and etching is performed by exposing a water to the plasmatized gas.

By sputtering with ions in plasma, chemical reaction by radicals, and the like, anisotropic etching and isotropic etching are performed. By selectively using such etching, components and wirings having various structures can be formed on the surface of the wafer.

When a processing shape of the wafer by the plasma etching is different from a design, the various formed components cannot implement functions thereof. Therefore, many techniques regarding process monitor for monitoring and stabilizing the etching processing of the wafer have been proposed.

For example, process monitor that measures thickness of a film formed on the wafer or a depth of a groove or a hole formed on the wafer by measuring reflected light from the wafer during the etching processing is also called a film thickness and depth monitor, and is used for end point determination and the like of the etching processing. Hereinafter, the film thickness and depth monitor will be simply referred to as a film thickness monitor.

PTL 1 discloses a method of improving processing accuracy using a film thickness monitor. More specifically, PTL 1 discloses that a film thickness measurement apparatus equivalent to a thick thickness monitor using plasma light as a light source is used to detect a timing immediately before complete removal of a film to be processed to end etching processing, and then the etching processing is performed by switching to conditions for highly selectively etching portions to be processed and portions not to be processed.

PTL 2 discloses technique for improving film thickness and depth measurement accuracy of a film thickness monitor. More specifically, PTL 2 discloses that, by using an external light source instead of plasma light as a light source for irradiating a wafer, a light source variation of the light source is reduced, and highly accurate measurement of film thickness and depth can be implemented.

### CITATION LIST

### Patent Literature

PTL 1: JP2006-119145A
PTL 2: JP2004-507070A

### SUMMARY OF INVENTION

### Technical Problem

In the manufacture of a semiconductor device, portion, at which an electronic circuit having various functions and a wiring are formed, and a boundary line between devices are formed in a specific layout on a water, and a device for implementing , a desired function is manufactured. For example, a memory device includes a memory portion for storing data, a circuit portion for storing and erasing data in the memory, and the like. A logic device includes a calculation portion for calculating digital data, a memory portion for temporarily storing calculation results, and the like. A layout of the portion, at which the electronic circuits are formed, and the boundary line of the devices vary depending on the device. Hereinafter, the layout on the water is generally referred to as a pattern layout.

Since there are various pattern layouts as described above, in order to perform end point determination using a film thickness monitor and achieve highly accurate processing in the device manufacturing process, it is preferable to measure reflected light reflected at a processing target region being processed in the process. For example, in a memory cell formation process of a memory device, it is preferable to acquire reflected light not at a boundary portion of a device or a circuit portion of data recording and erasing but at a memory cell portion that is a processing target region.

Here, when positions of a light irradiation port (also referred to as an irradiator) and a light measurement port (also referred to as a light receiving unit) are fixed in a film thickness monitor that irradiates a wafer with light from an external light source via the light irradiation port and measures reflected light received via the light measurement port, a position on the wafer for measuring the reflected light is uniquely determined and is a fixed position. Specifically, a position where a perpendicular bisector of a line segment connecting two ports intersects the wafer is a center of a monitor position for measuring the reflected light.

In the case of using the film thickness monitor in which the positions of the light irradiation port and the light measurement port are fixed as described above, it is difficult to measure reflected light. reflected at a processing target region of the wafer normally in the manufacturing process of devices of various pattern layouts. Therefore, due to the pattern layouts of the devices on the wafer, the accuracy of measuring the film thickness: and depth on the wafer by the film thickness monitor decreases, and it may be difficult to highly accurately perform the end point determination using the film thickness monitor.

The techniques of the present disclosure have been made in view of such circumstances, and an object thereof is to provide a plasma processing apparatus and a plasma. processing method capable of measuring reflected light reflected in a processing target region regardless of a pattern layout of a device.

### Solution to Problem

A representative technique of techniques of the present disclosure is a plasma processing apparatus including: a processing chamber inside a vacuum chamber; a Sample stage disposed in the processing chamber and having an upper surface on which a wafer to be processed is placed; a light irradiation unit having a plurality of irradiators configured to emit light to different positions toward a surface of the wafer placed on the sample stage; a light receiving unit configured to receive reflected light obtained by reflecting the light emitted from the plurality of irradiators by the wafer; and a processing amount. detection unit configured to detect a processing amount of the wafer based on information obtained from the reflected light received by the light receiving unit during processing of the wafer. The processing amount detection unit determines an irradiator that is to perform light irradiation from among the plurality of irradiators based on a difference between information on reflection positions on the wafer where light emitted from the respective irradiators is reflected and information on a processing position of the wafer, and detects the processing amount of the water by using the determined irradiator.

### Advantageous Effects of Invention

Effects obtained by the representative technique of the techniques of the present disclosure can be briefly described as follows. According to the technique of the present disclosure, it is possible to normally measure reflected light from a processing target region regardless of a pattern layout of a wafer. As a result, highly accurate film thickness measurement and end point determination can be implemented. Consequently, it is possible to implement highly accurate processing of a device. Problems, configurations, and effects other than those described above will be clarified by the following description of embodiments.

### BRIEF DESCRIPTION OF DRAWINGS

FIG. 1 is a diagram illustrating an overall configuration of a plasma processing apparatus according to Embodiment 1.

FIG. 2 is a diagram illustrating an outline of a configuration of a wafer processing device according to Embodiment 1.

FIG. 3 is a diagram. Schematically illustrating a configuration of an optical system according to Embodiment 1.

FIG. 4 is a diagram schematically illustrating an example of a pattern layout of a wafer in Embodiment 1.

FIG. 5 is a functional block diagram of a processing amount calculation unit according to Embodiment 1.

FIG. 6A is a graph illustrating a spectrum of reflected light from an electronic circuit portion of the wafer in Embodiment 1.

FIG. 6B is a graph illustrating a spectrum of reflected light from a peripheral portion of the wafer in Embodiment 1.

FIG. 7 is a diagram schematically illustrating a positional relationship between a light irradiation unit and a light receiving unit according to Embodiment 2.

FIG. 8 is a diagram illustrating a processing position of a wafer and a monitor position in Embodiment 2.

FIG. 9 diagram schematically illustrating a positional relationship between a light irradiation unit and a light receiving unit according to Embodiment 3.

FIG. 10 is a diagram illustrating an example of a processing position of a water and a monitor position in Embodiment 3.

FIG. 11 is a graph illustrating a spectrum of reflected light obtained by trial irradiation in Embodiment 4.

FIG. 12 is a graph illustrating an example of a calculation result of an error value between a spectrum of reflected light at each monitor position and a reference spectrum in Embodiment 6.

### DESCRIPTION OF EMBODIMENTS

Hereinafter, embodiments of the technique according to the present disclosure will be described in detail with reference to the drawings. In the drawings, the same components are denoted by the same reference signs in principle, and a repeated description thereof is omitted. In the drawings, in order to facilitate the understanding of the invention, each component may be schematically illustrated, and thus a width, a thickness, a shape, and the like of the component are just an example as compared with its actual form and do not limit the interpretation of the present disclosure.

### Embodiment 1

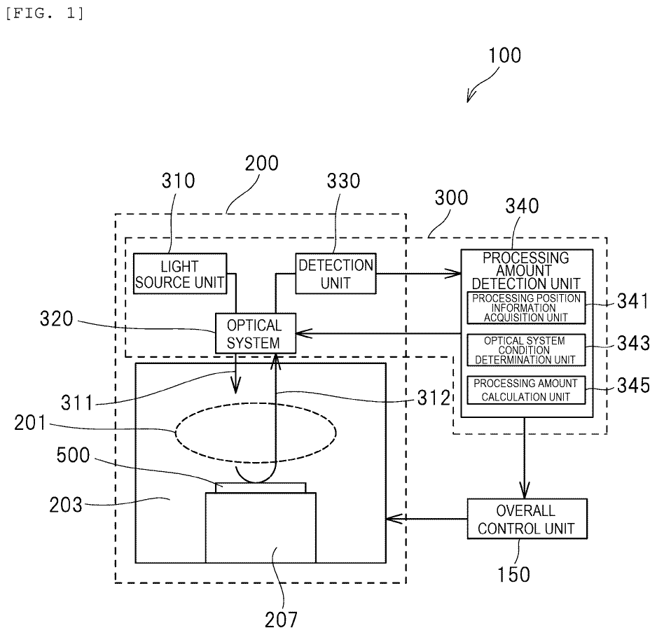

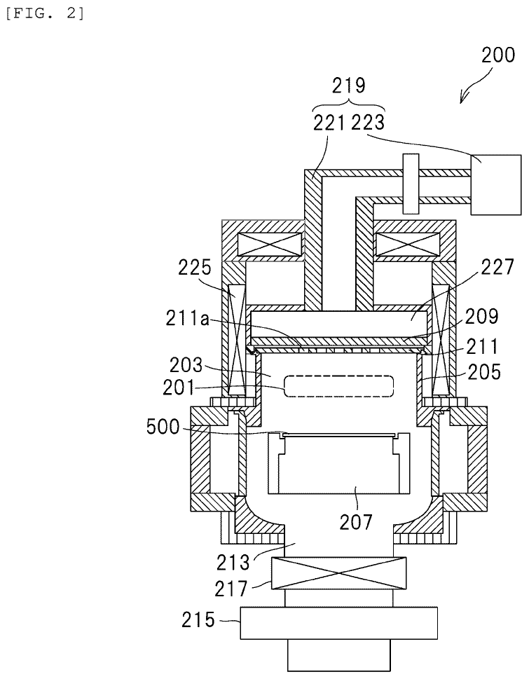

FIG. 1 is a diagram illustrating an outline of an overall configuration of a plasma processing apparatus according to Embodiment 1. FIG. 2 is a diagram illustrating an outline of a configuration of a wafer processing device according to Embodiment 1. FIG. 3 is diagram schematically illustrating a configuration of an optical system according to Embodiment 1.

As illustrated in FIG. 1, a plasma processing apparatus 100 according to the embodiment includes a wafer processing device 200 that performs etching processing (plasma processing) on a wafer 500 to be processed, and a processing amount measurement device 300 that measures a processing amount (etching amount) of the wafer 500 by the wafer processing device 200.

### Wafer Processing Device

First, an outline of a configuration of the water processing device 200 will be described. As an example, the water processing device 200 according to the embodiment uses an electric field of microwaves as an electric field for forming plasma, causes electron cyclotron resonance. (ECB) between the electric field of microwaves and a magnetic field to form the plasma, and performs etching processing on a processing object such as a semiconductor wafer (hereinafter, simply referred to as a water) using the plasma. That is, the wafer processing device 200 can also be called a plasma etching apparatus.

As illustrated in FIG. 2, the wafer processing device 200 includes a container including a processing chamber 203 in which plasma 201 is formed, for example, a vacuum chamber 205. In the processing chamber 203, a sample stage 207 on which the wafer 500 to be processed is placed is disposed below a space where the plasma 201 is formed.

An upper portion of the processing chamber 203 is closed by, for example, a disc-shaped dielectric window member 209. Further, a shower plate 211 constituting a circular ceiling surface of the processing chamber 203 is provided below the window member 209. The shower plate 211 in a circular plate shape has a plurality of gas introduction holes 211a formed through a central portion thereof, and an etching processing gas is introduced into the processing chamber 203 through the gas introduction holes 211a.

An exhaust port 213 connected to the processing chamber 203 is provided in a lower portion of the vacuum chamber 205. Further, below the processing chamber 203, there are provided a vacuum pump 215 such as a turbo-molecular pump for exhausting and depressurizing a gas in the processing chamber 203, and an exhaust amount adjustment valve 217 for increasing or decreasing area of a flow channel to adjust a flow rate of speed of an exhaust gas.

An electric field and magnetic field formation unit 219 that forms an electric field and a magnetic field for generating the plasma 201 in the processing chamber 203 is disposed above the vacuum chamber 205. The electric field and magnetic field formation unit 219 includes a waveguide 221 and an electric field generation power supply 223, and radio frequency electric field oscillated from the electric field generation power supply 223 is transmitted through the waveguide 221 and introduced into the processing chamber 203.

Magnetic field generation coils 225 are disposed around a lower end of the waveguide 221 and around the vacuum chamber 205. The magnetic field generation coil 225 includes an electromagnet and a yoke to which a direct current is supplied to form a magnetic field.

In the wafer processing device 200 having such a configuration, microwaves are oscillated from the electric field generation power supply 223 in a state where a processing gas is introduced into the processing chamber 203 through the gas introduction hole 211a of the shower plate 211. The electric field of microwaves passes through the window member 209 and the shower plate 211 and is supplied downward to the processing chamber 203 from above. Further, a magnetic field generated by the direct current supplied to the magnetic field generation coil 225 is supplied into the processing chamber 203 to cause an interaction with the electric field of microwaves to cause the ECR. By the ECR, atoms or molecules of the processing gas are excited and dissociated or ionized, and the high-density plasma 201 is generated in the processing chamber 203. Then, the semiconductor wafer 500 placed on the sample stage 207 is subjected to the etching processing (plasma processing) by the plasma 201.

### Overall Control Unit

As illustrated in FIG. 1, the plasma processing apparatus 100 includes an overall control unit 150 that comprehensively controls operations of the plasma processing apparatus 100.

The overall control unit 150 includes, for example, a calculation unit such as a central processing unit (CPU), a random access memory (RAM) unit such as semiconductor memory, a storage unit such as a solid state drive (SSD) or a hard disk drive (HDD), and a communication unit. Instead of a CPU, the overall control unit 150 may use an application specific integrated circuit (ASIC) or a programmable logic device (PLD) such as a field programmable gate array (FPGA).

The overall control unit 150 controls operations of the wafer processing device 200, which is a Plasma etching apparatus, as one type of control of the plasma processing apparatus 100. The overall control unit 150 performs, for example, introduction of a gas into the processing chamber 203, generation and control of the plasma. 201, and application of a voltage to the wafer 500 performed by a radio frequency power supply (not shown). In other words, the overall control unit 150 performs synchronization, timing adjustment, and the like between the devices such that desired etching processing for the wafer 500 is implemented in the processing chamber 203.

Further, when pulsing the plasma 201, control of pulsation is also performed by the overall control unit 150. At this time, on and off are switched by modulation of voltage application by a radio frequency power supply for converting an etching gas into plasma, modulation of microwave irradiation, or the like, and the plasma 201 is pulsed. Further, the plasma 201 is also pulsed by modulation of an introduction time of the etching gas.

### Processing Amount Measurement Device

As described above, the plasma processing apparatus 100 includes the processing amount measurement device 300 that measures the processing amount (etching amount) of the wafer 500 by the wafer processing device 200. The processing amount measurement device 300 can also be called a film thickness monitor that measures a thickness of a film formed on the wafer 500 and a depth of a groove or a hole formed on the wafer 500.

The processing amount measurement device 300 includes a light source unit 310, an optical system 320, and a detection unit 330. The light source unit 310, the optical system 320, and the detection unit 330 are disposed in a cavity 227 that is a space between the waveguide 221 and the window member 209 of the wafer processing device 200 described above, for example. For example, the optical system 320 is disposed on the window member 209.

The light source unit 310 emits continuous light from ultraviolet to infrared. However, when the processing amount measurement device 300 measures the processing amount using a specific wavelength, in other words, when performing the film thickness and depth measurement, it is sufficient for the light source unit 310 to emit a light of a specific wavelength.

Light emitted from the light source unit 310 is introduced into the processing chamber 203 through the optical system 320, and is irradiated onto the semiconductor wafer 500 as irradiation light 311.

More specifically, as illustrated in FIG. 3, the optical system 320 includes a light irradiation unit (also referred to as a multiple point irradiation port) 321. The light irradiation unit 321 includes a plurality of irradiators (also referred to as irradiation optical ports) 323 for emitting, as the irradiation light 311, Light emitted from the light source unit 310 into the processing chamber 203.

The plurality of irradiators 323 are disposed above the processing chamber 203 (for example, in the cavity 227) as described above, and are disposed at different positions in an in-plane direction of the wafer 500. As an example, the plurality of irradiators 323 are arranged in a row in a radial direction of the wafer 500.

Although not illustrated, each of the irradiators 323 includes a collimator lens and an optical fiber that connects the collimator lens and the light source unit 310. When irradiating the wafer 500 with the irradiation light 311, the light emitted from the light source unit 310 is introduced into one or more specific optical fibers. Accordingly, the irradiation light 311 is irradiated onto the wafer 500 via one or more irradiators 323.

Switching of light input from the light source unit 310 to each irradiator 323 is performed by a fiber switch (not illustrated) or the like. The configuration of the irradiator 323 is not particularly limited as long as the wafer 500 in the processing chamber 203 can be irradiated with the light emitted from the light source unit 310 as the Irradiation light 311.

Although an example in which the plurality of irradiators 323 are linearly arranged on a plane parallel to the wafer 500 is described in the embodiment, the arrangement of the irradiators 323 is not limited thereto. The irradiators 323 may be disposed in, for example, a two-dimensional plane, or may be disposed in a three-dimensional space above the wafer 500.

The optical system 320 further includes at least one light receiving unit (light receiving port) 325 for inputting, to the detection unit 330, reflected light 312 reflected by the wafer 500. In the embodiment, the optical system 320 includes one light receiving unit 325. Although not illustrated, the light receiving unit 325 includes a collimator lens and an optical fiber that connects the collimator lens and the detection unit 330.

The optical system 320 may include a plurality of light receiving units 325. In this case, each light receiving unit 325 includes a collimator lens and an optical fiber. Further, in the detection of the reflected light 312 from the wafer 500, light received by the specific light receiving unit 325 is input to the detection unit 330. That is, light from a specific optical fiber constituting the light receiving unit 325 is input to the detection unit 330.

Here, the reflected light 312 detected by the detection unit 330 is light reflected around a position at which a perpendicular bisector of a straight line connecting the irradiator 323, which is emitting light, and the light receiving unit 325 connected to the detection unit 330 intersects with the wafer 500. The reflection position of the reflected light 312 input to the light receiving unit 325 on the wafer 500 is referred to as a “monitor position”.

Although a configuration is described in the embodiment in which the processing amount measurement device 300 includes the light source unit 310 and the optical system 320 that are independent of each other, the configuration of the processing amount measurement device 300 is not limited thereto. In the processing amount measurement device 300, the light source unit 310 may be integrated with the optical system 320. For example, each of the irradiators 323 provided in the optical system 320 may include an LED serving as a light source. In this case, in the processing amount measurement device 300, the light source unit 310 is provided in the optical system 320.

Further, in order to efficiently irradiate the water 500 with the irradiation light 311, each irradiator 323 may be implemented by combining an LED and a collimator lens.

For example, the processing amount measurement device 300 may include, as the light irradiation unit 321, a display type light source having a specific size and a specific number of pixels. Also in this case, the light source unit 310 is provided in the optical system 320.

The detection unit 330 includes, for example, a spectrometer, disperses introduced light, and detects a Light amount for each wavelength. When measuring the processing amount of the wafer 500 (the film thickness and the depth on the wafer 500) using a specific wavelength, the detection unit 330 may include a photodetector or the like, not limited to the spectrometer.

In this case, if the light introduced into the detection unit 330 is only light of a desired specific wavelength, the detection unit 330 may include only the photodetector. When introducing continuous light, the detection unit 330 is provided with a device such as a monochromator, which selects only the specific wavelength, upstream of the photodetector.

The detection of light by the detection unit 330 is continuously performed at a fixed interval, for example, at 2 Hz or 10 Hz during the plasma processing of the wafer 500. Detection data detected by the detection unit 330 is transmitted to a processing amount detection unit 340.

Similarly to the overall control unit 150, the processing amount detection unit 340 includes, for example, a calculation unit such as a CPU, a RAM unit, a storage unit, and a communication unit, and performs calculation of the processing amount (etching amount) of the wafer 500 and the like. In the embodiment, the processing amount detection unit 340 includes processing position information acquisition unit 341, an optical system condition determination unit 343, and a processing amount calculation unit 345.

The processing position information acquisition unit 341 acquires information on a processing position of the wafer 500 to be processed (hereinafter also referred to as processing position information). As an example, prior to the etching processing, the processing position information acquisition unit 341 acquires the processing position information of the wafer 500 from a processing information management unit (not illustrated).

Here, the information on the processing position of the water 500 is, for example, information such as coordinates of a processing position in a pattern layout of the wafer 500 or coordinates specifying a processing target region including a processing position.

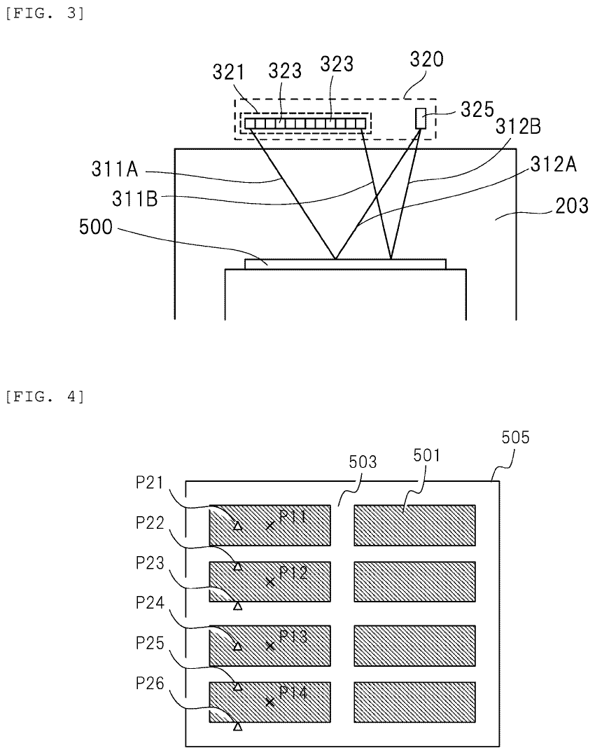

FIG. 4 is a diagram schematically illustrating an example of a pattern layout of a wafer in Embodiment 1. As illustrated in FIG. 4, the wafer 500 to be processed has an individual pattern 505 including an electronic circuit portion 801 and its peripheral portion 503 in a pattern layout. The individual pattern 505 is repeatedly present on the wafer 500.

As an example, the electronic circuit portion 501 has a size of about 5 mm in length and about 15 mm in width. A size of the individual pattern 505, that is, a size up to a boundary between adjacent individual patterns 505 is about 30 mm in length and about 30 mm in width.

The etching processing is performed on the electronic circuit portion 501 in the individual pattern 505 of the wafer 500. That is, in the example illustrated in FIG. 4, the electronic circuit portion 501 is the processing position or processing target region.

Therefore, information supplied from the processing position information acquisition unit 341 to the optical system condition determination unit 343 is, for example, coordinates of a processing position in the electronic circuit portion 501 For example, the processing position information acquisition unit 341 supplies information on coordinates of processing positions P11 to P14 in respective electronic circuit portion 501 to the optical system condition determination unit 343.

The processing positions P11 to P14 can be set to any positions in the electronic circuit portion 501. For example, the processing positions P11 to P14 are preferably set near a center of the electronic circuit portion 501.

The information acquired by the processing position information acquisition unit 341 is supplied to the optical system condition determination unit 343. The optical system condition determination unit 343 determines a condition of the optical system 320 based on the processing position information on the wafer 500 supplied from the processing position information acquisition unit 341.

The optical system condition determination unit 343 determines, as one of conditions of the optical system 320, the irradiator 323 that is to perform the light irradiation from the plurality of irradiators 323 based on a difference between information on reflection positions (monitor positions) on the wafer 500 where light emitted from the respective irradiators 323 is reflected and information on the processing position of the wafer 500, and detects the processing amount of the wafer 500 using the determined irradiator 323.

In the embodiment, the optical system condition determination unit 343 selects, from among the plurality of irradiators 323 described above, the irradiator 323 whose distance between the reflection position (monitor position) on the wafer 500 where the light emitted from the irradiator 323 is reflected and the processing position of the wafer 500 is less than a set distance set in advance. The set distance may be set freely, and is preferably set to be as small as possible.

The optical system condition determination unit 343 determines conditions of the optical system 320 by comparing coordinates specifying a processing position or processing target region of the water 500 transmitted from the processing position information acquisition unit 341 and coordinates of a monitor position selectable by the optical system 320.

For example, in FIG. 3, reflected light 312A is light obtained by reflecting, on the wafer 500, irradiation light 311A emitted from the irradiator 323 farthest from the light receiving unit 325. Reflected light 312B is light obtained by reflecting, on the wafer 500, irradiation light 311B emitted from the irradiator 323 closest to the light receiving unit 325.

As can be seen from the drawing, by changing the position irradiated with light of the light irradiation unit 321, that is, by changing the irradiator 323 to be used, the reflection position (monitor position) on the wafer 500 of the reflected light 312 received by the light receiving unit 325 is changed.

In the example illustrated in FIGS. 3, 12 irradiators 323 are arranged at an interval of about 10 mm. In this case, by switching the irradiator 323 that emits light, monitor positions of the reflected light 312 detected by the light receiving unit 325 can be controlled to be at an interval of about 5 mm. That is, the optical system condition determination unit 343 can determine the desired irradiator 323 from the plurality of irradiators 323 having different monitor positions at an interval of about 5 mm.

In the embodiment, for example, the optical system condition determination unit 343 specifies a monitor position having coordinates closest to the coordinates of the processing position of the wafer 500, and determines the irradiator 323 corresponding to the specified monitor position.

As an example, as illustrated in FIG. 4, it is assumed that monitor positions P21 to P26 selectable by the optical system 320 exist in the individual pattern 505. In this case, the optical system condition determination unit 343 extracts a combination having the shortest distance between the coordinates of the processing positions P11 to P14, which are processing position information, and coordinates of the monitor positions P21 to P26. In this example, a combination of the monitor position P21 and the processing position P11 and a combination of the monitor position P24 and the processing position P13 are extracted. Then, the optical system condition determination unit 343 selects one of the monitor position P21 and the monitor position P24, and determines the irradiator 323 corresponding to the selected monitor position.

As described above, when information the coordinates of the plurality of processing positions P11 to P14 is supplied from the processing position information acquisition unit 341, the optical system condition. determination unit 343 may specify monitor positions having coordinates closest to the coordinates of the respective processing positions P11 to P14, and determine one or more irradiators 323 that perform the light irradiation so as to. achieve the specified monitor positions.

When the optical system 320 includes a plurality of light receiving units 325 and the monitor position on the wafer 500 changes depending on selection of the light receiving unit 325, the optical System condition determination unit 343 may select and determine the light receiving unit 325 in accordance with the irradiator 323.

Further, for example, when the processing position information of the wafer 500 is coordinates specifying a processing target region, the optical system condition determination unit 343 may determine plurality of irradiators 323 Corresponding to a plurality of monitor positions included in the processing target region as the irradiator 323 that performs the light irradiation.

The conditions of the optical system 320 determined by the optical system condition determination unit 343 in this manner are supplied to the processing amount calculation unit 345.

The processing amount calculation unit 345 calculates the processing amount (etching amount) of the water 500 using the specific irradiator 323 based on the information supplied from the optical system condition determination unit 343. For example, the processing amount calculation unit 345 controls a state of the optical system 320 to irradiate the wafer 500 with the irradiation light 311 from the specific irradiator 323, and causes the light receiving unit 325 to receive the reflected light 312. Then, the processing amount calculation unit 345 calculates the processing amount (etching amount) of the wafer 500 based on a detection result introduced from the detection unit 330.

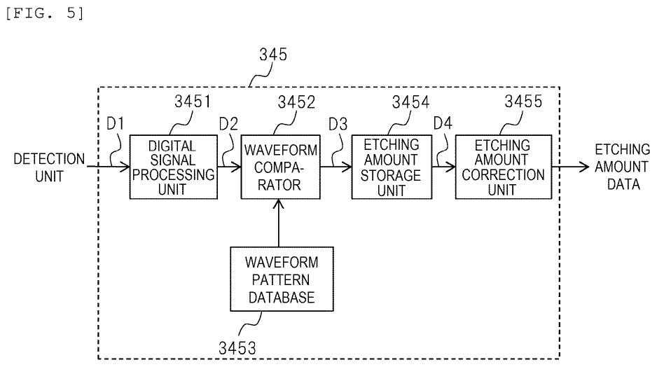

FIG. 5 is a functional block diagram of the processing amount calculation unit according to Embodiment 1, in particular, a configuration of a functional block for calculating a processing amount of a water.

As illustrated in FIG. 5, time series data D1 of a light amount of each wavelength introduced from the detection unit 330 into the processing amount calculation unit 345 is first subjected to removal and correction of various kinds of noise and variation by a digital signal processing unit 3451, and then is supplied to a waveform comparator 3452 as time series data D2.

In removing noise on a time axis of each wavelength, for example, a low-pass filter is used. For example, in a case of removing light amount offset of each wavelength and observing a change in light amount over time, signal processing of calculating a light amount change amount between time-points or a differential value may be used. For example, an S-G method along the time axis is used in the differential value calculation. Further, for example, when there is fluctuation in the light amount of all wavelengths that changes at the same magnification, signal processing is applied that normalizes the light amount of each wavelength by the average value of the sum of absolute values of the light amount of all wavelengths.

The time series data D2 introduced into the waveform comparator 3452 is compared with a waveform pattern database 3453 that is light amount data of each wavelength corresponding to etching amounts acquired in advance. Here, in the waveform comparator 3452, the waveform pattern database (light amount data) 3453 and the time series data D2 currently obtained are compared, a waveform pattern closest to a current pattern is obtained, and the processing amount of the water 500 is specified based on the closest waveform pattern.

A specified processing amount D3 is stored in an etching amount storage unit 3454. The light amount data of each wavelength in the waveform pattern database 3453 is data processed in signal processing performed by the digital signal processing unit 3451, and is preferably processed in the same signal processing as: the time series data D2. However, the light amount data and the time series data may not necessarily be performed in the same signal processing. The etching amount storage unit 3454 transmits time series data D4 of the processing amount to a processing amount correction unit 3455.

The processing amount correction unit 3455 corrects the processing amount at each time-point based on time Series transition of calculated processing amounts. As an example, when there is fluctuation caused by noise or the like in the time series transition of the calculated processing amounts, the processing amount correction unit 3455 linearly approximates the time transition of the processing amounts to correct the processing amount at each time. The processing amount correction unit 3455 outputs a corrected processing amount as processing amount data. For example, the processing amount correction unit 3455 outputs the corrected processing amount as processing amount data to the overall control unit 150.

Although the waveform comparator 3452 and the waveform pattern database 3453 are used in determining the processing amount (etching amount) D3 using the time series data D2 in the above example, machine learning may be used. In this case, the time series data D2 is input using information in the waveform pattern database 3453, a learning model or an approximation function is generated using the etching amount D3 as an output, and the etching amount D3 is calculated (estimated) using the generated learning model approximate function.

In the above example, the waveform comparator 3452 specifies the processing amount D3. Error values for two or more waveforms, as well as intensity values or frequency values for the respective waveforms, may also be calculated. For example, when calculating an error value for an entire spectrum that is light amount data of wavelengths, the waveform comparator 3452 calculates an error of the light amount of each wavelength or an absolute value thereof, and calculates a sum of the errors or absolute values as the error value. For example, when calculating an error value for specific wavelengths in the spectrum, the waveform comparator 3452 calculates errors of the light amount of the specific wavelengths or absolute values thereof, and calculates a sum of the errors or absolute values as the error value. For example, when calculating an intensity of the spectrum, the waveform comparator 3452 calculates, as an intensity value, a sum of intensities of all wavelengths in the spectrum or intensities of specific wavelengths. For example, when calculating a frequency value of the spectrum, the waveform comparator 3452 performs Fourier transform on the spectrum in a wavelength direction to calculate a vibration frequency of the intensity in the wavelength direction as the frequency value.

Then, the overall control unit 150 performs end point determination in the etching processing of the wafer 500 based on the processing amount data output from the processing amount calculation unit 345. A method of the end point determination in the etching processing of the wafer 500 is not particularly limited. As an example, the following method is exemplified.

The overall control unit 150 compares the acquired processing amount data with predetermined target processing amount, and determines whether the current processing amount reaches the target processing amount. When it is determined that the current processing amount reaches the target processing amount, the etching processing is ended.

According to the plasma processing apparatus 100 of Embodiment 1 described above, it is possible to normally measure the reflected light from the processing target region regardless of the pattern layout of the wafer 500. As a result, highly accurate processing amount measurement (film thickness measurement) and end point determination of processing of the wafer can be implemented. Consequently, it is possible to implement highly accurate processing of the device.

In the plasma processing apparatus 100 according to Embodiment 1, since the processing amount of the wafer 500 is measured based on the detection result of the reflected light 312 at the monitor position in the processing target region, it is possible to more accurately measure the processing amount and perform the end point determination of wafer processing.

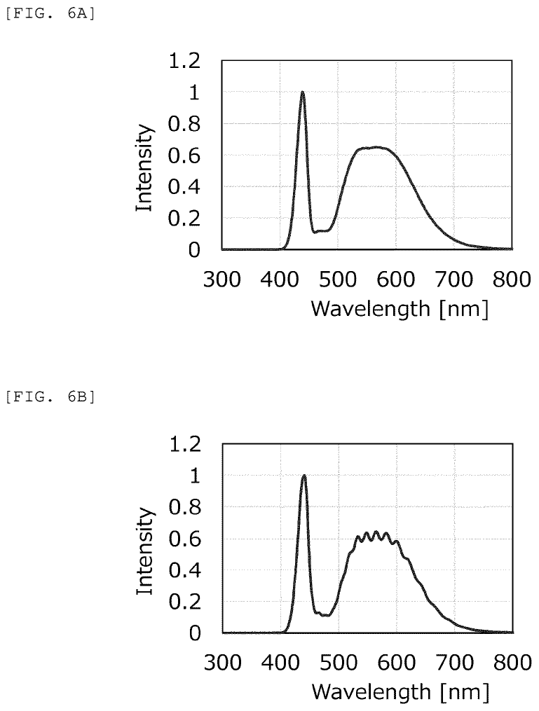

FIG. 6A is a graph illustrating a spectrum of reflected light from an electronic circuit portion of a wafer in Embodiment 1. FIG. 6B is a graph illustrating a spectrum of reflected light from a peripheral portion of the wafer in Embodiment 1. As can be seen from FIG. 6A and FIG. 6B, spectrums of the reflected light 312 vary depending on an acquisition position of the reflected light 312. That is, the spectrum (FIG. 6A) of the reflected light 312 in the electronic circuit portion 501 serving as the processing target region is different from the spectrum (FIG. 6B) Of the reflected light 312 in the peripheral portion 503 outside the processing target region. Therefore, the measurement of the processing amount of the wafer 500 is preferably performed based on the reflected light at the monitor position in the electronic circuit portion 501 that is the processing target region.

In the embodiment, the processing amount of the wafer 500 is measured using the reflected light 312 reflected at the monitor position P21 pr the monitor position P24 positioned in the electronic circuit portion 501 as described above. Accordingly, a spectrum observed during the etching processing has the same shape as in FIG. 6A. Therefore, based on the spectrum of the reflected light 312, the processing amount of the wafer 500 is easily determined, and highly accurate end point determination can be implemented. Further, by automatically stopping the etching processing based on the end point determination, the processing accuracy can be improved. Specifically, an error from a target of processing dimension can be reduced to, for example, about 1 mm or less.

The above-described pattern layout of the wafer 500 is an example. In other pattern layouts, reflected light at a monitor position closest to a processing position can be measured by controlling a reflection position (monitor position) on the water 500 of the reflected light 312 to be measured. Further, reflected light in a processing target region can be measured. That is, even for a wafer having another pattern layout, highly accurate processing can be implemented.

Although so-called spectrum matching is used as a method of specifying the processing amount (etching amount) in the embodiment, the method of specifying the processing amount is not particularly limited. For example, the processing amount may be specified by using light amount data of a specific wavelength in a spectrum or feature data extracted from the spectrum.

Although the monitor position is set to one in the embodiment, there may be a plurality of monitor positions. In this case, for example, an average spectrum obtained during the processing at the plurality of monitor positions is measured. Accordingly, the processing amount measurement, that is, the film thickness and depth measurement (estimation) can be performed using information on an average processing state of processing distribution in the surface of the wafer 500.

Although the processing amount detection unit 340 provided in the processing amount measurement device 300 detects the processing amount of the wafer 500 by the etching processing in the embodiment, the overall control unit 150 may detect the processing amount of the wafer 500, for example. That is, the plasma processing apparatus 100 includes the processing amount detection unit 340 separately from the overall control unit 150, and the overall control unit 150 may also function as the processing amount detection unit 340.

### Embodiment 2

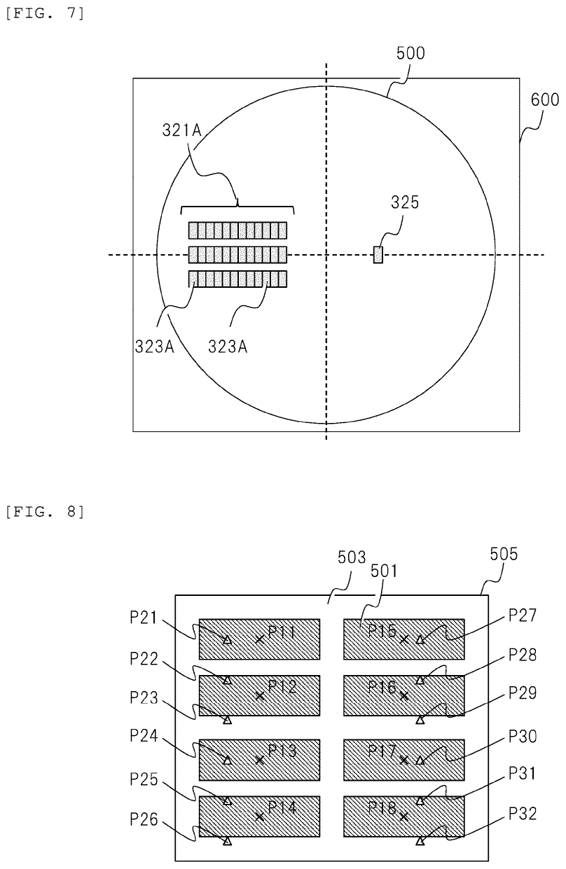

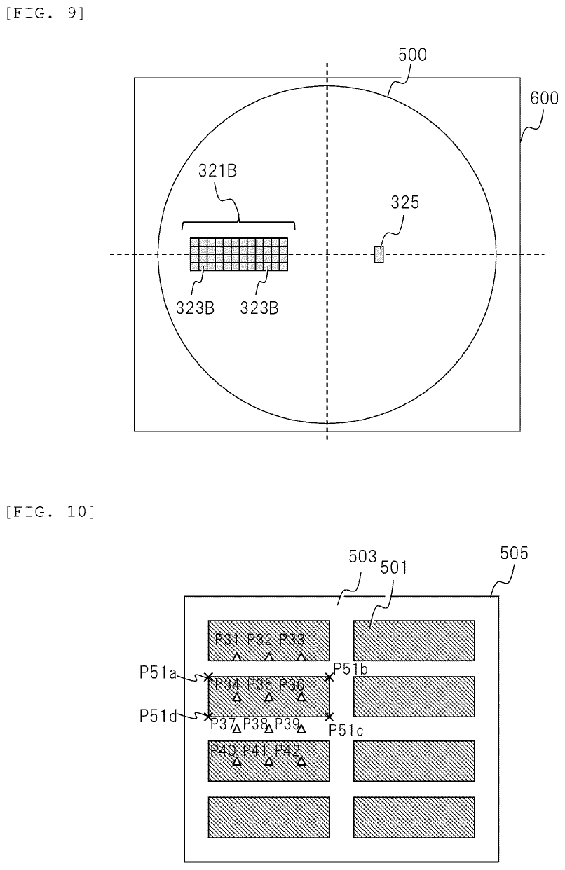

FIG. 7 is a diagram schematically illustrating positional relationship between a light irradiation unit and a light receiving unit according to Embodiment 2, and is a view of a processing chamber viewed from above. FIG. 8 is a diagram illustrating a processing position of a water and a monitor position in Embodiment 2.

In Embodiment 1, the example in which the irradiators. 323 of the light irradiation unit 321 are arranged in a row is described. On the other hand, in Embodiment 2, as illustrated in FIG. 7, a plurality of irradiators 323A constituting a light irradiation unit 321A are arranged in a two-dimensional plane. In other words, the plurality of irradiators 323A constituting the light irradiation unit 321A are arranged in a plurality of rows in an optical system installation plane 600. Since other portions are similar to those in Embodiment 1, a description thereof is omitted. The optical system installation plane 600 means a plane in which the optical system 320 is installed.

In the embodiment, the light irradiation unit 321A includes 36 irradiators 323A. The irradiators 323A are arranged in a two-dimensional plane. Specifically, three rows are arranged in the optical system installation plan 600, each row having 12 irradiators 323A.

Since the plurality of irradiators 323A are arranged in the two-dimensional plane in this manner, the monitor position that the optical system 320 can select can be increased. That is, since the plurality of irradiators 323A are arranged in the two-dimensional plane, the monitor position to which the irradiation Light 311 can be irradiated via the optical system 320 can be increased.

In Embodiment 1, there are 6 monitor positions that the optical system 320 can select, that is, the monitor positions P21 to P26 (see FIG. 4). On the other hand, in Embodiment 2, as illustrated in FIG. 8, there are 12 monitor positions that the optical system 320 can select, that is, monitor positions P21 to P32. Therefore, for processing positions P11 to P18 of the wafer 500, the optical system condition determination unit 343 can determine a mor appropriate monitor position and the corresponding irradiator 323A.

Similarly to Embodiment 1, the optical system condition determination unit 343 compares coordinates of the processing positions P11 to P18 of the water 500 with coordinates of the monitor positions P21 to P32, and extracts a combination having the shortest distance between the coordinates. For example, in the example in FIG. 8, the combination having the shortest distance between coordinates is a combination of the processing position P15 and the monitor position P27, and a combination of the processing position P17 and the monitor position P30.

The processing amount calculation unit 345 controls the light irradiation unit 321 and the like of the optical system 320 such that a reflection position of the reflected light 312 is the monitor position P27 or the monitor position P30. That is, the processing amount calculation unit 345 performs film thickness and depth estimation (estimation of the etching amount) during etching processing and end point determination of the etching processing based on a detection result of the reflected light 312 reflected at the monitor position 227 or the monitor position P30.

Accordingly, similarly to Embodiment 1, it is possible to improve the accuracy of the measurement of an etching processing amount and the end point determination, and thus it is possible to implement highly accurate processing of a device.

In the example illustrated in FIG. 8, it is considered that the monitor positions P21, 224, P27, and P30 fall within the electronic circuit portion 501 that is processing target region. Therefore, by emitting light from the plurality of irradiators 323A such that spectrums of the reflected light 312 from the monitor positions P21, P24, P27, and P30 are simultaneously detected by the light receiving unit 325, it is possible to implement more appropriate end point determination based on an average processing state of a plurality of electronic circuit portions 501.

### Embodiment 3

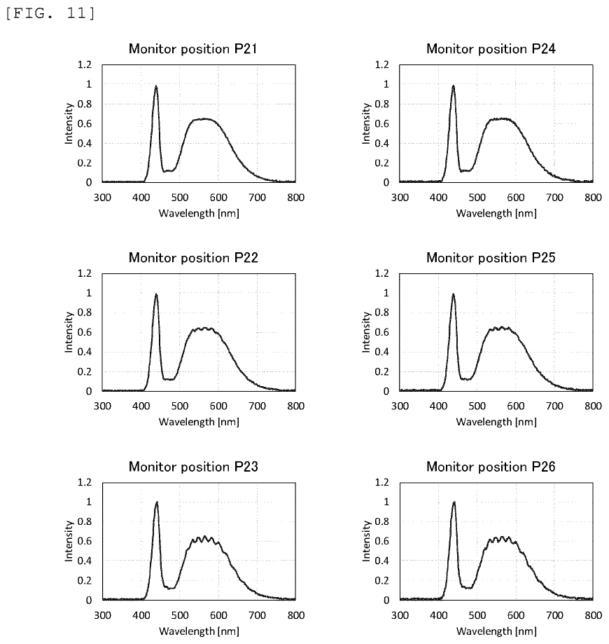

FIG. 9 is a diagram schematically illustrating a positional relationship between a light irradiation unit and a light receiving unit according to Embodiment 3, and is a view of processing chamber viewed from above. FIG. 10 is a diagram illustrating an example of a processing position of a wafer and a monitor position in Embodiment 3.

The plasma processing apparatus 100 according to Embodiment 3 includes, as a light irradiation unit 321B constituting the optical system 320, a plurality of irradiators 323B implemented by lens integrated LEDs. Other configurations are similar to those in Embodiment 2, and thus a description thereof is omitted.

As illustrated in FIG. 9, the light irradiation unit 321B is implemented by 48 lens integrated LEDs that are disposed in the optical system installation plane 600. That is, also in Embodiment 3, the plurality of irradiators 323B are arranged in a two-dimensional plane.

In the embodiment, the processing position information acquisition unit 341 acquires, as information on processing position, information on coordinates positions P51a to P51d at four corners of the electronic circuit portion 501 having a substantially rectangular shape as illustrated in FIG. 10 that is information on a processing target region, and supplies the information to the optical system condition determination unit 343.

The optical system condition determination unit 343 selects, from a plurality of monitor positions, a monitor position having a distance from the electronic circuit portion 501 defined by the coordinates of the positions P51a to P51d shorter than a set distance set in advance, and more preferably a monitor position having the shortest distance from the electronic circuit portion 501. More preferably, the optical system condition determination unit 343 selects a monitor position positioned in the electronic circuit portion 501.

In the example illustrated in FIG. 10, the electronic circuit portion 501, which is the processing target region of the wafer 500, is defined as a range specified by the positions P51a to B51d. In the example illustrated in FIG. 10, the monitor position that the optical system 320 can select in the vicinity of the electronic circuit portion 501 includes monitor positions P31 to P42.

The optical system condition determination unit 343 compares the range of the processing position defined by the positions P51a to PS1d with the monitor positions P31 to P42, and determines the monitor position in the electronic circuit portion 501 that is the processing target region. In the example illustrated in FIG. 10, three monitor: positions B34, P35, and P36 are determined as the monitor positions in the electronic circuit portion 501.

By performing measurement of an etching processing amount (film thickness measurement during etching) and end point determination of the processing based on a detection result of the reflected light 312 reflected at the monitor positions P34, P35, and P36 determined as described above, it is possible to improve the accuracy of the processing amount measurement and the end point determination of the processing as in the above-described embodiments. Consequently, it is possible to implement highly accurate processing of a device.

### Embodiment 4

Embodiment 4 is an example in which, in the configuration of Embodiment 1, coordinates of a measurement position of an inspection device that is an external device are used as processing position information of the wafer 500. Since other portions are similar to those in Embodiment 1, a description thereof is omitted here.

The wafer 500 to be processed by the plasma processing apparatus 100 is subjected to etching processing by the wafer processing device 200, and thereafter is subjected to processing shape measurement by an electron microscope.

Although not illustrated, the plasma processing apparatus 100 is communicably connected to the electron microscope via a cable or the like. The processing position information acquisition unit 341 acquires a measurement position of a processing shape by the electron microscope, and supplies the acquired measurement position as processing position information to the optical system condition determination unit 343.

For example, when the position at which the processing shape is measured by the electron microscope corresponds to the processing position P13 on the wafer 500 in the example illustrated in FIG. 4, the processing position information acquisition unit 341 acquires the coordinates of the processing position P13 as processing position information, and supplies the acquired processing position information to the optical system condition determination unit 343.

With the plasma processing apparatus according to Embodiment 4, it is also possible to improve the accuracy of processing amount measurement and end point determination of the processing as in the above-described embodiments. Consequently, it is possible to implement highly accurate processing of a device.

### Embodiment 5

Embodiment 5 is an example in which the optical system condition determination unit 343 determines the irradiator 323, which is to perform light irradiation, based on a result of trial irradiation by the light irradiation unit 321. Since other portions are similar to those in Embodiment 1, a description thereof is omitted here.

More specifically, in the plasma processing apparatus 100 according to Embodiment 5, prior to etching processing of the wafer 500, trial irradiation for the wafer 500 is performed via the irradiators 323 of the light irradiation unit 321. Then, the optical system condition determination unit 343 determines the irradiator 323 used for processing amount measurement based on a spectrum of the reflected light 312 acquired by the trial irradiation. Therefore, in the embodiment, supply of information on a processing position from the processing position information acquisition unit 341 to the optical system condition determination unit 343 is not performed.

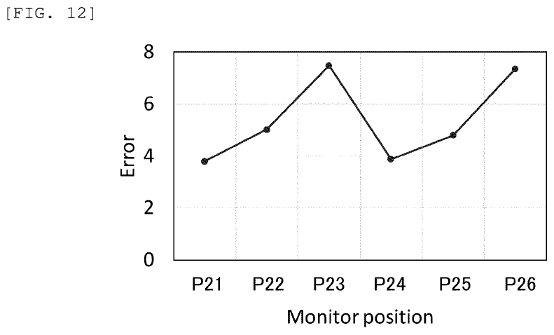

For example, in the example illustrated in FIG. 4, a result of performing trial irradiation on the monitor positions P21 to P26 in the individual pattern 505 of the wafer 500 and acquiring spectrums of the reflected light 312 reflected at the monitor positions P21 to P26 is illustrated in FIG. 11.

As illustrated in FIG. 11, shapes of the spectrums of the reflected light 312 differ between the monitor positions P21 to B26. In Embodiment 5, the optical system condition determination unit 343 compares spectrums of the reflected light 312 at respective monitor positions B21 to P26 with a reference spectrum Set in advance, and determines the monitor position where a spectrum closest to the reference spectrum is obtained. In the embodiment, the reference spectrum is a spectrum of the reflected light at a processing position. Therefore, the monitor position determined as described above in the embodiment can also be referred to a monitor position that is closest to the processing position of processing target region of the water 500.

With the plasma processing apparatus according to Embodiment 5, it is also possible to improve the accuracy of processing amount measurement and end point determination of the processing as in the above-described embodiments. Consequently, it is possible to implement highly accurate processing of a device.

In the embodiment, an example in which the spectrum of reflected light at the processing position is set as the reference spectrum is described. however, the reference spectrum may not necessarily be a spectrum of reflected light at the processing position, and may be a spectrum of reflected light at any position of the water 500.

As described above, in the embodiment, an example is described in which the processing amount detection unit 340 selects, from among the plurality of irradiators 323, the irradiator 323 having the shortest distance between a reflection position on the water 500 where light emitted from the irradiator 323 is reflected and the processing position of the water 500.

However, the processing amount detection unit 343 may not necessarily select the irradiator 323 having the shortest distance between the reflection position on the wafer 500 and the processing position of the wafer 500. The processing amount detection unit 340 may determine the irradiator 323 that is to perform light irradiation from among the plurality of irradiators 323, based on difference between information on reflection positions on the wafer 500 where light emitted from the respective irradiators 323 is reflected and information On the processing position of the wafer 500.

### Embodiment 6

Embodiment 6 is an example in which a monitor position is determined from a signal intensity based on a result of trial irradiation in Embodiment 5. Since other portions are similar to those in Embodiment 5, a description thereof is omitted.

More specifically, in the embodiment, the optical system condition determination unit 343 calculates an error value between a spectrum of the reflected light 312 at each monitor position obtained by the trial irradiation and a reference spectrum, and determines the monitor position based on the error value. The error value is calculated as a sum of error absolute values of respective wavelengths in the spectrum.

FIG. 12 is a graph illustrating an example of a calculation result of an error value between a spectrum of reflected light at each monitor position and a reference Spectrum in Embodiment 6. In the graph of FIG. 12, a horizontal axis represents coordinates of the monitor position, and a vertical axis represents the error value.

Regarding the spectrum of the reflected light 312, it can be defined that, as the error value is smaller, the spectrum is closer to the reference spectrum and the signal intensity is higher (noise is less). Therefore, in the case of the example illustrated in FIG. 12, it is determined that the signal intensity is the highest for the reflected light at the monitor position P21 having the smallest error value. The monitor position P21 is determined as the monitor position used for film thickness and depth estimation and end point determination.

With the plasma processing apparatus according to Embodiment 6, it is also possible to improve the accuracy of processing amount measurement and end point determination of the processing as in the above-described embodiments. Consequently, it is possible to implement highly accurate processing of a device.

In the embodiment, the signal intensity is calculated based on the error value from the reference spectrum, and a method of calculating the signal intensity is not limited thereto. For example, in the case of trial irradiation, when reflectance at the processing position of the wafer 500 is high and reflectance at other positions is low, an intensity value, which is a sum of intensities of respective wavelengths, may be used as the signal intensity of a spectrum of reflected light obtained by the trial irradiation.

Further, for example, when vibration in light intensity in a wavelength direction due to a thick transparent film occurs in a spectrum of reflected light reflected at the processing position of the water 500, and there is no vibration in light intensity in the wavelength direction in other portions, the signal intensity may be calculated using a frequency value that is a frequency of the vibration of the light intensity in the wavelength direction in the spectrum obtained by the trial irradiation.

In this case, the signal intensity can be defined as an error amount from a target of the frequency value. Specifically, a monitor position at which the error amount is the smallest is determined as the monitor position at which the signal intensity is the highest.

Although the technique of the disclosure has been specifically described above based on the embodiments, the technique of the disclosure is not limited to the embodiments, and it is needless to say that various modifications can be made without departing from the gist of the present disclosure. For example, the above-described embodiments are described in detail to facilitate understanding of the technique of the present disclosure, and are not necessarily limited to those including all the configurations described above. In addition, another configuration can be added to, deleted from, or replaced with a part of a configuration of each embodiment.

### REFERENCE SIGNS LIST

100: plasma processing apparatus
150: overall control unit
200: wafer processing device
201: plasma
203: processing chamber
205: vacuum chamber
207: sample stage
209: window member
211: shower plate
211a: gas introduction hole
213: exhaust port
215: vacuum pump
217: exhaust amount adjustment valve
219: electric field and magnetic field formation unit
221: waveguide
223: electric field generation power supply
225: magnetic field generation coil
227: cavity
300: processing amount measurement device
310: light source unit
311: irradiation light
312: reflected light
320: optical system
321: light irradiation unit (multiple point irradiation port)
323: irradiator (irradiation optical port)
325: light receiving unit (light receiving port)
330: detection unit
340: processing amount detection unit
341: processing position information acquisition unit
343: optical system condition determination unit
345: processing amount calculation unit
3451: digital signal processing unit
3452: waveform comparator
3453: waveform pattern database
3454: etching amount storage unit
3455: processing amount correction unit
500: wafer (semiconductor wafer)
501: electronic circuit portion
503: peripheral portion
505: individual pattern
600: optical system installation plane

1. A plasma processing apparatus comprising:
a processing chamber inside a vacuum chamber;
a sample stage disposed in the processing chamber and having an upper surface on which a wafer to be processed is placed;
a light irradiation unit including a plurality of irradiators configured to emit light to different positions toward a surface of the wafer placed on the sample stage;
a light receiving unit configured to receive reflected light obtained by reflecting the light emitted from the plurality of irradiators by the wafer; and
a processing amount detection unit configured to detect a processing amount of the wafer based on information obtained from the reflected light received by the light receiving unit during processing of the wafer, wherein
the processing amount detection unit determines an irradiator that is to perform light irradiation from among the plurality of irradiators based on a difference between information on reflection positions on the wafer where light emitted from the respective irradiators is reflected and information on a processing position of the wafer, and detects the processing amount of the wafer by using the determined irradiator.

2. The plasma processing apparatus according to claim 1, wherein
the processing amount detection unit selects, from among the plurality of irradiators, an irradiator whose distance between a reflection position on the wafer where light emitted from the irradiator is reflected and the processing position of the wafer is less than a set distance set in advance, and detects the processing amount of the wafer by using the selected irradiator.

3. The plasma processing apparatus according to claim 2, wherein
the processing amount detection unit selects, from among the plurality of irradiators, an irradiator whose distance between a reflection position on the wafer where irradiation light emitted from the irradiator is reflected and the processing position of the wafer is smallest, and detects the processing amount of the wafer by using the selected irradiator.

4. The plasma processing apparatus according to claim 2, wherein
the processing amount detection unit calculates a distance between the reflection position on the wafer and the processing position based on coordinates of the processing position on the surface of the wafer and coordinates of the reflection position.

5. The plasma processing apparatus according to claim 1, wherein
the processing amount detection unit selects the irradiator used to detect the processing amount of the wafer, based on a result of comparison between a spectrum of the reflected light received by the light receiving unit and a reference spectrum set in advance.

6. The plasma processing apparatus according to claim 1, wherein
each of the irradiators includes a lens and an optical fiber.

7. The plasma processing apparatus according to claim 1, wherein
each of the irradiators includes an LED light source.

8. A plasma processing method using a plasma processing apparatus,
the plasma processing apparatus including
a processing chamber inside a vacuum chamber,
a sample stage disposed in the processing chamber and having an upper surface on which a wafer to be processed is placed,
a light irradiation unit including a plurality of irradiators configured to emit light to different positions toward a surface of the wafer placed on the sample stage, and
a light receiving unit configured to receive reflected light obtained by reflecting the light emitted from the plurality of irradiators by the wafer,
the plasma processing method comprising:
determining an irradiator that is to perform light irradiation from among the plurality of irradiators based on a difference between information on reflection positions on the wafer where light emitted from the respective irradiators is reflected and information on a processing position of the wafer, detecting a processing amount of the wafer by using the determined irradiator, and controlling processing of the wafer based on the detected processing amount.

9. The plasma processing method according to claim 8, wherein
an irradiator whose distance between a reflection position on the wafer where light emitted from the irradiator is reflected and the processing position of the wafer is less than a set distance set in advance is selected from among the plurality of irradiators, and the processing amount of the wafer is detected by using the selected irradiator.
